(19) United States
(12) Patent Application Publication
(10) Pub. No.: US 2006/0120138 A1
(43) Pub. Date: Jun. 8, 2006

(54) Semiconductor memory with volatile and non-volatile memory cells

(75) Inventors: Corvin Liaw, Munchen (DE); Josef Willer, Riemerling (DE); Michael Kund, Tuntenhausen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/260,691

(22) Filed: Oct. 28, 2005

(30) Foreign Application Priority Data
Oct. 29, 2004 (DE) 10 2004 052 586.2
Sep. 22, 2005 (DE) 10 2005 045 312.0

(51) Int. Cl. G11C 11/24

(52) U.S. Cl. 365/149

(57) ABSTRACT

The present invention relates to a semiconductor memory with a volatile memory device, in particular a DRAM memory device, and with a non-volatile memory device. The volatile memory device is electrically coupled with the non-volatile memory device, and the non-volatile memory device has a polymer memory device adapted to be switched between two states of information.

### CLAIMS FOR PRIORITY

This application claims priority to German Application Nos. 10 2004 052 586.2 filed Oct. 29, 2004 and 10 2005 045 312.0 filed Sep. 22, 2005 which are incorporated herein, in their entirety, by reference.

### TECHNICAL FIELD OF THE INVENTION

The invention relates to a semiconductor memory with a combination of volatile and non-volatile memory cells. The invention further relates to the operation, the design, and to differing layout concepts for a semiconductor memory with a combination of volatile memory cells and non-volatile polymer memory cells.

### BACKGROUND OF THE INVENTION

A semiconductor memory device usually comprises a cell field consisting of a plurality of memory cells, and a matrix of column and line supply lines or word and bit lines, respectively. The memory cells are each positioned at the crosspoints of the electroconductive supply lines that are each electrically connected with the memory cell via an upper electrode or top electrode and a lower electrode or bottom electrode. To perform a change of the information content in a particular memory cell at the addressed crosspoint, or to recall the content of the memory cell, the corresponding word and bit lines are selected and impacted either with a write current or with a read current.

Different kinds of semiconductor memories are known, e.g. a RAM (Random Access Memory). A RAM memory device is a memory with optional access, i.e. data can be stored under a particular address and can be read out again under this address later. By selectively applying a voltage at a corresponding selection transistor via the column and row supply lines, it is possible to store an information unit (bit) in a capacitor during a write process and to recall it again during a read process via the selection transistor.

A particular kind of semiconductor memories are DRAMs (Dynamic Random Access Memory) which comprise in general only one single, correspondingly controlled capacitive element, e.g. a trench capacitor, with the capacitance of which one bit each can be stored as charge. DRAM memory cells stand out by especially short access times. The charge or the information stored, however, remains for a relatively short time only in a DRAM memory cell, so that a “refresh” must be performed regularly, wherein the corresponding information content is written in the memory cell again or is refreshed, respectively. The problem of the leaking currents in the memory capacitor existing with the DRAM memory concept, which may result in a loss of charge or a loss of information, respectively, has so far been solved insufficiently only by the permanent refreshing of the stored charge.

In contrast to DRAMs, no “refresh” has to be performed in the case of SRAMs (Static Random Access Memories) since the data stored in a SRAM memory cell remain stored as long as an appropriate supply voltage is fed to the SRAM. To this end, every memory cell of the SRAMs comprises as a rule a larger number of, for instance, 6 transistors, which entails the need for a larger space on a silicon substrate. It is, however, generally intended to accommodate as many memory cells as possible in a memory device, so that they have to be realized, or to be scaled, respectively, as simple as possible and on the smallest possible space.

Various non-volatile memory devices are known which are based on different physical principles. It is only with non-volatile memory devices (NVMs) such as EPROMs, EEPROMs, and flash memories, that the stored data remain stored even if the supply voltage is switched off. The flash memory concept, however, has the problem of restricted write and read cycles. Moreover, relatively high voltages are needed with flash devices since the charges have to overcome a barrier layer.

In addition to the above-described memory devices, memory types on the basis of polymers or specific molecules have also been suggested. The concept of the polymer memory cells deals with complex molecules that are adapted to assume two different states that are connected by an intramolecular charge flow. Such polymer memory cells may be addressed, written and read out electrically. In the case of modern polymer memory cells, an electrochemically active material of at least two different molecule or polymer layers that are each adapted to be reversibly transferred from an oxidized form to a reduced form and thus form an electrochemical Red/Ox pair is positioned in a volume between an upper electrode or top electrode and a lower electrode or bottom electrode. These molecule or polymer layers are in electric connection both with one another and with the respectively adjacent electrode layers of the top or bottom electrode, respectively.

As has been explained above, the DRAM semiconductor memory devices have the advantage of short write and read times, but the disadvantage of a volatile data content, which necessitates a permanent refreshing of the information stored. Contrary to this, the non-volatile polymer memory cells have the advantage that the information stored therein remains stored for a relatively long time even without any voltage supply. In prior art, e.g. in US 2004/0016947 A1, combinations of DRAM semiconductor memories and FLASH memory devices have already been suggested, which, however, have the above-mentioned disadvantages of the FLASH memory devices.

In the following, the basic functioning of a polymer memory cell is described. A typical structure of a polymer memory cell comprises, for instance, a first layer of an electroconductive material, a second layer being arranged on the first layer and being in electric connection therewith, the second layer comprising a first chemical compound that is adapted to be reversibly transferred from an oxidized form to a reduced form, a third layer arranged on the second layer, the third layer comprising a second chemical compound that is adapted to be reversibly transferred from a reduced form to an oxidized form, and a fourth layer of an electroconductive material being arranged on the third layer and being in electric connection therewith.

The memory cell thus comprises, with the second and third layers, at least two different molecule or polymer layers forming an electrochemical Red/Ox pair. If an appropriate voltage is applied to the electroconductive first layer and the electroconductive fourth layer, the first chemical compound comprised in the second layer yields electrons to the electroconductive first layer, thus oxidizing the first chemical compound. Simultaneously, electrons flow from the electroconductive fourth layer into the third layer, so that the second chemical compound comprised therein is transferred to the reduced form by the acceptance of electrons. If the polarity of the voltage is reversed, the memory cell may be written back to the original state. For equalizing the charges generated by the oxidation or reduction, respectively, of the first and second chemical compounds, protons flow from the second layer into the third layer, so that the memory cell altogether remains electrically neutral.

The information content of the polymer memory cell is determined by the state of oxidation of the first and second chemical compounds that are comprised in the second or third layer, respectively, of the memory cell. In the first state, the first chemical compound is in its reduced form and the second chemical compound is in its oxidized form. By applying a voltage, an oxidation or reduction, respectively, of the chemical compounds is effected. In the second state, the first chemical compound is then in its oxidized form whereas the second chemical compound is in its reduced form. By reversing the polarity of the voltage, swapping between the two states may be effected.

If the first chemical compound in its oxidized form and the second chemical compound in its reduced form are electrically neutral, the two logic states in the memory cell may be characterized in that in the first state the molecules are available in their neutral form and in the second state the molecules are available in ionic form. Thus, a purely electric reading out of the cell state is possible.

Another type of polymer memory devices is described in IEDM, 2003, Paper #10.2, “Organic Materials for High-Density Non-Volatile Memory Applications.”, by R. Sezi et al, Infineon Technologies. Such polymer memory cells are good to integrate in electronic circuits in that they are arranged on a substrate in which integrated circuits are structured. To this end, the polymer memory cells may be arranged in a memory field or array, respectively, with the word and bit lines being arranged at right angles to each other, so that they form crosspoints at each of which a polymer memory cell is formed.

### SUMMARY OF THE INVENTION

The present invention combines the advantageous characteristics of volatile memory devices, on the one hand, and of non-volatile memory devices, on the other hand, without the disadvantages of restricted write and read cycles and of high voltages for the write and read processes.

According to one embodiment of the invention, there is a semiconductor memory with a volatile memory device, in particular a DRAM memory device, and with a non-volatile memory device, wherein the volatile memory device is electrically coupled with the non-volatile memory device, and wherein the non-volatile memory device comprises a polymer memory device adapted to be switched between two states of information.

According to another embodiment of the present invention, volatile DRAM memory devices are used in combination with resistively switching memory devices in the form of non-volatile polymer memory devices instead of FLASH memory cells. Thus, the present invention provides the combination between volatile memory devices with short access times in the form of DRAM memory devices and non-volatile memory devices in the form of resistively switching polymer memory cells that are adapted to immediately reload the information stored in the DRAM at the time it was switched off.

This way, on the one hand, the cell size of the memory is reduced since, depending on the embodiment, a reduced number of control gate lines or no control gate line at all is needed anymore. Due to the reduced number of control gate lines, a simpler operation is also achieved than in prior art. Furthermore, distinctly lower voltage values than with conventional semiconductor memories that are operated in combination with flash memory cells are required in the case of the inventive semiconductor memory. Another advantage of the inventive semiconductor memory consists in that the writing rate of a polymer memory is higher than that of a flash memory cell.

The present invention is primarily based on the combination of a volatile DRAM semiconductor memory with non-volatile polymer memory cells which enable to load information stored in the polymer memory cells into the DRAM semiconductor memory. Likewise, the information from the volatile DRAM semiconductor memory be transferred to the non-volatile polymer memory. By this, it may be achieved that the information stored in the DRAM semiconductor memory, or the state of the DRAM semiconductor memory available, respectively, prior to the switching off is stored in the non-volatile polymer memory. On switching on of the DRAM semiconductor memory, the information stored in the non-volatile polymer memory or the state available, respectively, prior to the switching off of the DRAM semiconductor memory may be again taken over in the DRAM semiconductor memory directly after the switching on. Thus, an instantaneous switching on of a system may be achieved without substantial time delay.

### BRIEF DESCRIPTION OF THE DRAWINGS

In the following, the invention will be explained in more detail with respect to several preferred embodiments and the enclosed drawings. In the drawings:

FIG. 1A shows an electric circuit for a semiconductor memory according to a first preferred embodiment of the present invention.

FIG. 1B shows a further electric circuit for a semiconductor memory according to a variation of the first preferred embodiment of the present invention.

FIG. 2A shows an electric circuit for a semiconductor memory according to a second preferred embodiment of the present invention.

FIG. 2B shows a further electric circuit for a semiconductor memory according to a variation of the second preferred embodiment of the present invention.

FIG. 3 shows a diagram for illustrating the switching characteristics of a resistively switching polymer memory device.

FIG. 4 shows a diagram for illustrating the switching characteristics of a zener diode,

FIG. 5 shows a lateral sectional view through a semiconductor substrate in which there is structured a semiconductor memory according to a preferred embodiment of the present invention.

FIGS. 6 to 9 show the layout for semiconductor memories according to preferred embodiments of the present invention.

FIG. 10 a lateral sectional view through a semiconductor substrate in which there is structured a semiconductor memory according to a further preferred embodiment of the present invention with the layout illustrated in FIG. 9.

FIG. 11 shows an electric circuit diagram for an inventive semiconductor memory according to the folded bit line concept in accordance with the embodiment of the present invention as illustrated in FIGS. 5 and 6.

FIG. 12 shows an electric circuit diagram for an inventive semiconductor memory according to the folded bit line concept in accordance with the embodiment of the present invention as illustrated in FIGS. 9 and 10 of the present invention.

FIG. 13 shows an electric circuit diagram for a semiconductor memory designed in accordance with the open bit line concept according to a further embodiment of the present invention.

### DETAILED DESCRIPTION OF THE INVENTION

The inventive semiconductor memory comprises a matrix consisting of word lines and bit lines that are preferably in orthogonal orientation to each other. According to a first preferred embodiment of a semiconductor memory with a combination of volatile and non-volatile memory devices according to the present invention, the resistively switching polymer memory device is coupled with an additional transistor each.

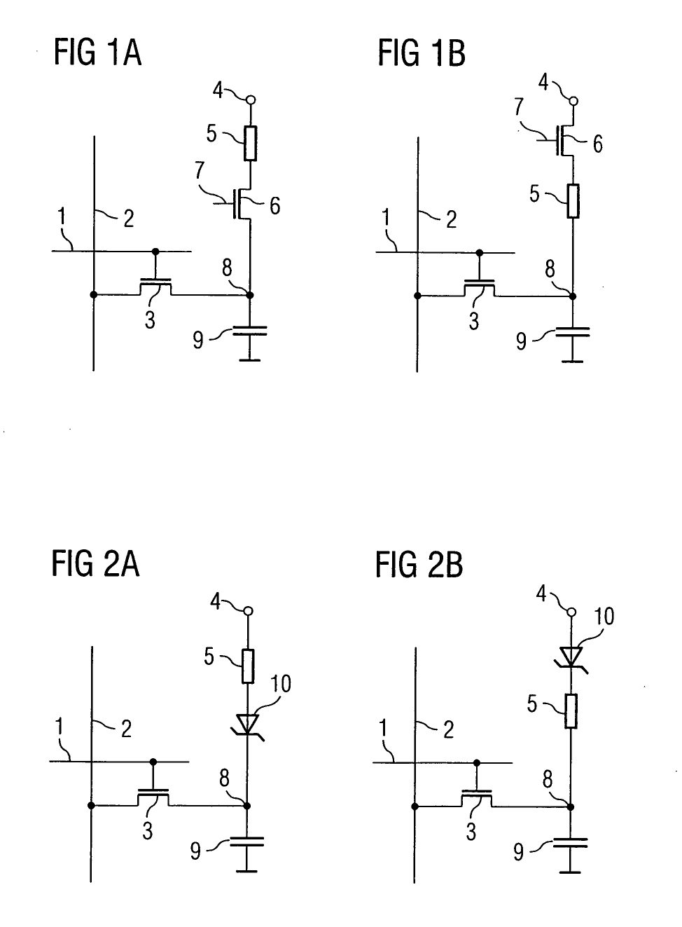

FIGS. 1A and 1B each show an embodiment of a circuit for a semiconductor memory according to the present invention, in which a non-volatile memory device and a volatile memory device are combined or electrically coupled with one another, respectively. As a non-volatile memory device, a polymer memory cell or a polymer memory device 5, respectively, with an additional transistor 6 is used, which are each positioned at the crosspoint between a word line 1 and a bit line 2.

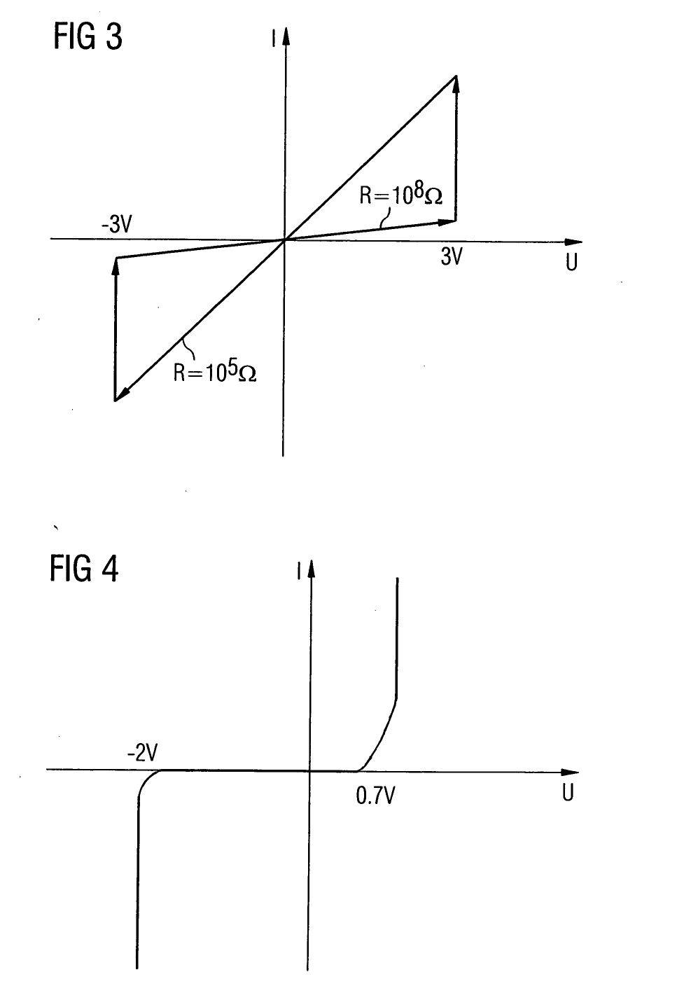

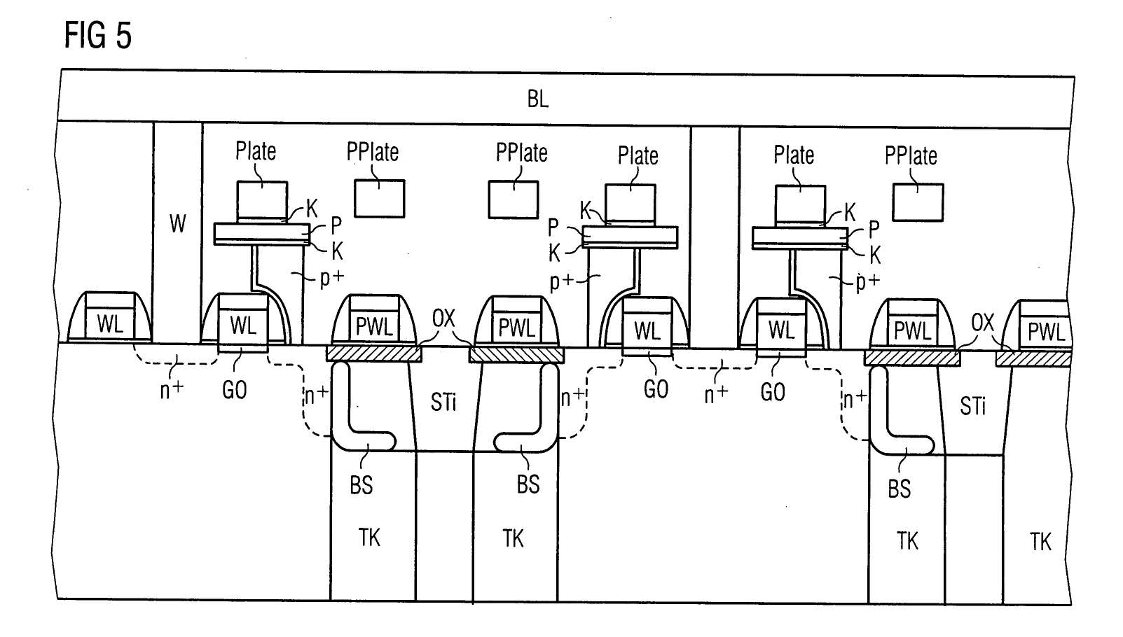

For better understanding of the circuits illustrated in FIGS. 1A and 1B, the switching behavior of a polymer memory device 5 is first of all described in more detail. FIG. 3 shows a diagram for illustrating the switching characteristics of a resistively switching polymer memory device 5. As may be seen from FIG. 3, the polymer memory device is highly resistive when the voltage U, starting out from 0V, is in a range below a positive threshold voltage, and has a resistance of approx. R=10⁸ Ω, so that a low current I flows through the polymer memory device. As soon as the voltage U has reached the positive threshold voltage of, for instance, 3V, the polymer memory device abruptly becomes lowly resistive and has a resistance of approx. R=10⁵ Ω, so that a higher current I may flow through the polymer memory device. With a negative threshold voltage of approx. −3V, the polymer memory device abruptly becomes highly resistive again and (again) has a resistance of approx. R=10⁸ Ω auf. This hysteresis-like switching behavior of the resistive polymer memory device is utilized with the electric circuits for semiconductor memories according to a first preferred embodiment of the present invention.

In the circuit illustrated in FIG. 1A, the polymer memory cell 5 is connected on one side via a plate connection 4 to a plate line (not illustrated) and on its other side via an additional transistor 6 with the capacitor 9 of a DRAM memory device. The additional transistor 6 comprises a control gate 7 that is contacted and controlled via a control gate line (not illustrated). Via a node 8, the capacitor 9 and the polymer memory device 5 are coupled with a word line transistor or selection transistor 3, respectively, of the DRAM memory device. The DRAM memory device 3, 9 is correspondingly controlled via the word line 1 and the bit line 2.

The embodiments of electric circuits illustrated in FIGS. 1A and 1B differ from one another in the order of the series connection of the polymer memory cell 5, the additional transistor 6, and the capacitor 9 of the DRAM memory device, with the basic operation remaining the same. In the embodiment illustrated in FIG. 1A, the order of the series connection starts at the plate connection 4 with the polymer memory device 5 via the additional transistor 6 to the capacitor 9. In the embodiment illustrated in FIG. 1B, the order of the series connection starts at the plate connection 4 with the additional transistor 6 via the polymer memory device 5 to the capacitor 9. Due to the differences in the layout, the leaking currents and/or the noise sensitivity of the semiconductor memory, either the one or the other embodiment of the circuit may be preferred.

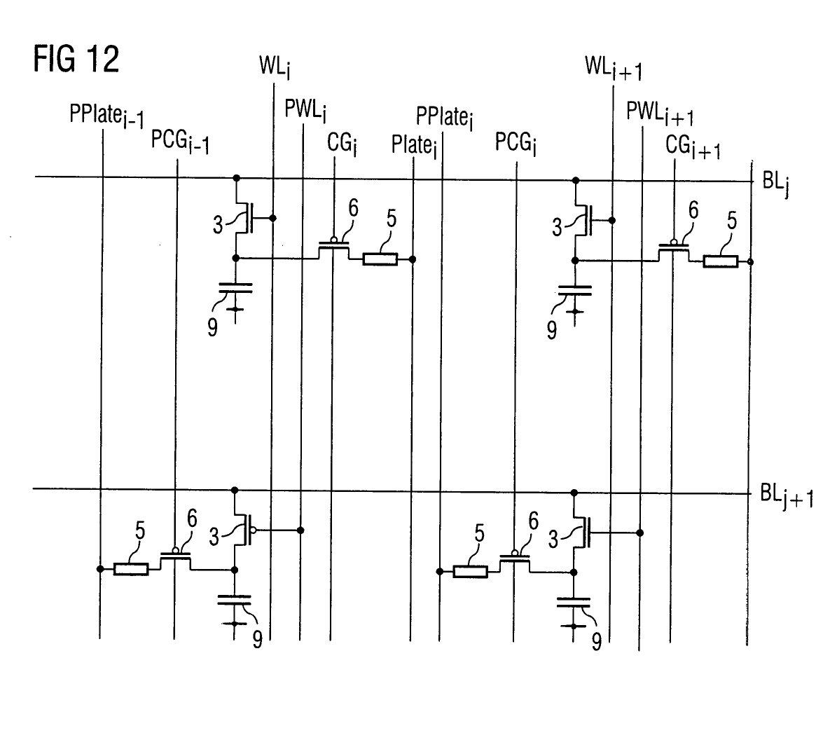

FIG. 12 shows an electric circuit diagram for a semiconductor memory according to the embodiment of the present invention illustrated in FIGS. 1A and 1B with an additional transistor, wherein the semiconductor memory is designed in accordance with the folded bit line concept. The folded bit line concept comprises a recurrent succession of electric lines that are arranged side by side and parallel to each other in the following order:

word line WL

passing word line PWL

control gate line CG

plate line Plate

passing plate line PPlate

passing control gate line PCG

These electric lines are crossed orthogonally by bit lines BLⱼ and BLⱼ₊₁. The volatile DRAM memory device comprises a word line transistor or selection transistor 3, respectively, and a capacitor 9. As to the bit line plane BLⱼ, the selection transistor 3 and the capacitor 9 of the DRAM memory device are each controlled via the word lines WLᵢ or WLᵢ₊₁, respectively, and the bit line BLⱼ. To this end, the word lines WLᵢ or WLᵢ₊₁, respectively, are each connected with the gates of the selection transistors 3 while the bit line BLⱼ is connected with the source/drain path of the selection transistors 3.

The non-volatile memory device comprises a polymer memory device P and an additional transistor 6. On the one side, the polymer memory device P is connected with the additional transistor 6, and on the other side with the plate line Plate. The control gate of the additional transistor 6 is contacted and controlled via the control gate line CG. Via a node, the additional transistor 6 is connected with the capacitor 9 of the DRAM memory device.

In the bit line plane BLⱼ₊₁, the selection transistor 3 and the capacitor 9 of the DRAM memory device are controlled via the passing word lines PWLᵢ or PWLᵢ₊₁, respectively, and the bit line BLⱼ₊₁. To this end, the passing word lines PWLᵢ or PWLᵢ₊₁, respectively, are each connected with the gates of the selection transistors 3 while the bit line BLⱼ₊₁ is connected with the source/drain path of the selection transistors 3. The polymer memory device P is, on the one side, again connected with the additional transistor 6, but on the other side with the passing plate line PPlate. Accordingly, the control gate of the additional transistor 6 is contacted and controlled via the passing control gate line PCG. In a further bit line plane BLⱼ₊₂ (not illustrated), the above-described structure of the bit line plane BLⱼ would recur. This structure recurs as many times as desired, which is indicated by the orders i−1, i and i+1 or j and j+1, respectively.

In the following, the operating mode of the circuits illustrated in FIGS. 1A, 1B, and 12 is described for a semiconductor memory according to the present invention. For reading out the value stored in the DRAM memory cell, the selected word line 1 is opened or activated, and a charge equalization between the capacitor 9 and the connected bit line 2 takes place. This charge equalization effects that the voltage of the corresponding bit line 2 and the node 8 either assumes approx. 0.9V or approx. 1.1V, depending on whether a value “logic Zero” or “logic One” was stored in the DRAM memory cell.

Subsequently, a sense amplifier (not illustrated) amplifies this voltage value and draws the corresponding bit line 2 and a reference bit line to the respective logic level. To this end, the selected bit line 2 is, if a voltage of 0.9V is measured there, taken to a low level, and the pertinent reference bit line to a high level. If a voltage of 1.1V is measured at the selected bit line, the sense amplifier takes it to a high level and the pertinent reference bit line to a low level. This voltage value of the bit line that has been amplified by the sense amplifier effects that the voltage at the capacitor again assumes the value of prior to the reading process, which corresponds to a refreshing of the information stored in the corresponding DRAM memory cells 3, 9. Subsequently, the word line 1 may again be closed or deactivated by eliminating the selection, this causing the bit line 2 to be disconnected from the capacitor.

Writing of the information contained in the DRAM memory device 3, 9 into the non-volatile polymer memory device 5 may be effected as follows (with the word line 1 being in the low state and the control gate 7 of the additional transistor 6 being in the high state): By applying a negative voltage at the plate connection 4 of the polymer memory device 5 of, for instance, Vplate=−1.7V, it is effected that a voltage of Vc−Vplate=3 is generated between the capacitor voltage Vc at the node 8 to the plate connection 4. The capacitor voltage Vc of the DRAM memory device 3 is approx. 1.3V to 1.8V (high state of the DRAM memory device), so that the voltage lies above the writing voltage of the polymer memory device 5. By the charging of the capacitor 9, the polymer memory resistance is written, i.e. it becomes lowly resistive.

If there is no charge on the capacitor 9 of the DRAM memory device (low state of the DRAM memory device), the voltage Vc−Vplate=1.7V is not sufficient to write the polymer memory device 5, and the electric resistance of the polymer memory device 5 remains highly resistive and is therefore not written. This transfer of the information contained in the DRAM memory device 3, 9 to the polymer memory cells 5 may be effected in parallel on a chip altogether on which there is a number of circuits illustrated in FIG. 1A or in FIG. 1B, or else in smaller memory blocks.

In the following, the operating mode of the circuits illustrated in FIGS. 1A and 1B is described for a semiconductor memory according to the present invention with respect to the loading of the respectively stored value from the non-volatile polymer memory 5 to the DRAM memory device 3, 9. To ensure a suitable initialization, the capacitor 9 is preferably first taken to a defined voltage level of e.g. 0V. This is effected by opening or activating, respectively, the word line 1 and e.g. connecting the bit line 2 with a mass connection of the memory device. Then, the word line 1 is closed or deactivated, respectively, and all control gates are preferably opened.

By applying a positive voltage that is lower than the deleting voltage VDel of the polymer memory device 5 at the plate connection 4, the corresponding value is transferred from the polymer memory device 5 to the DRAM memory device 3, 9. The polymer memory cell 5 is lowly resistive with an electric resistance of approx. 10⁵ Ω. The capacitor 9 is charged with the time constant ζ=Rsp×Csp=3.5 ns, i.e. after a period of approx. 3.5 ns the capacitor voltage Vc at the node 8 has reached approx. 63% of the voltage Vplate at the plate connection 4. Thus, a voltage at the plate connection 4 of Vplate=2.3V results, for instance, in a capacitor voltage at the node 8 of Vc=1.5V (high state of the DRAM memory device).

If, however, the polymer memory device 5 is in a highly resistive state, there results a time constant of ζ=Rsp×Csp=3500 ns. Within a charging time of 3.5 ns, 0.1% of the voltage Vplate is achieved. Thus, a voltage at the plate connection 4 of Vplate=2.3V results, for instance, in a capacitor voltage at the node 8 of Vc=0.0023V (low state of the DRAM memory device). This way, the original value of the DRAM memory device or the information originally stored in the DRAM memory device 3, 9, respectively, is restored in the DRAM memory.

In addition to the above described operating modes for the transfer of information between the non-volatile polymer memory 5 and the volatile DRAM memory device 3, 9, a regular operation is, of course, also possible with the semiconductor memory according to the invention, wherein the DRAM memory devices 3, 9 can be used as a conventional DRAM system memory. With this regular DRAM operation, the control gate 7 of the additional transistor 6 is in a low state or has a negative voltage. To minimize leaking currents, either the pn-junction of the additional transistor 6 or the polymer memory device 5 may be connected with the node 8, as with the circuits illustrated in FIG. 1A or 1B. Additionally or alternatively, the voltage Vplate at the plate connection 4 may be optimized, e.g. between a high and a low Vc level.

In the following, the operating mode for deleting the polymer memory devices 5 of a semiconductor memory according to the present invention will be described. The polymer memory cells 5 may be deleted both in the idle cycle of the DRAM memory if the DRAM memory is not accessed, and during the writing back of the information stored in the polymer memory (in parallel to this in another memory block), or during the reading out of the corresponding values from the polymer memory devices 5, respectively. In so doing, all the polymer memory devices 5 connected with the corresponding word line 1 are deleted. According to a further preferred embodiment of the present invention, these processes may also take place in parallel in a semiconductor memory.

For deleting the polymer memory devices 5, the word line 1 is first of all opened, which effects a charge sharing or a charge equalization, respectively, between the precharged bit line 2 and the capacitor 9. Then, the voltage at the bit line 2 or at the capacitor 9, respectively, increases or decreases and assumes, depending on the respectively stored value, finally a value of approx. 0.9 or approx. 1.1V in the manner that has already been described above. Prior to the evaluation by means of a sense amplifier, the word line 1 is closed and the control gate is opened by the word line transistor of the DRAM memory device 3. If a voltage of −4.5V is applied to the plate connection 4, the voltage Vplate is higher than the deleting voltage VDel of the polymer memory devices 5, this causing all polymer memory cells 5 of the corresponding word line 1 to be deleted. Subsequently, after the decreasing of the voltage at the plate connection 4 and with a closed control gate, the value that has now been amplified by the sense amplifier is again written in the capacitor 9 in that the word line transistor 3 of the DRAM memory device is opened again.

The voltages or logic levels, respectively, required for the above described operating modes for an inventive semiconductor memory according to the first preferred embodiment with an additional transistor are listed in the following Table.

| | V plate line | V control gate | V word line |
|---|---|---|---|
| Writing from | −1.7 V | High | Low |
| DRAM into poly- | | | |
| mer memory | | | |
| Loading from | 2.3 V | High | Low |
| polymer memory | | | |
| into DRAM | | | |
| DRAM operation | Approx. 0.9 V | Low | Depending on |
| | | | process |
| Deleting of | Approx. −4 V | As described | As described |
| polymer memory | | above | above |

In accordance with a second preferred embodiment of the inventive semiconductor memory, the polymer memory devices 5 are each coupled with the zener diode 10. FIGS. 2A and 2B each show a circuit for a second preferred embodiment of a semiconductor memory of the present invention in which a non-volatile and a volatile memory device are combined. As may be gathered from FIGS. 2A and 2B, the polymer memory device 5 is coupled with a zener diode 10 in the second preferred embodiment of an inventive semiconductor memory.

For better understanding of the circuits illustrated in FIGS. 2A and 2B, the switching behavior of a zener diode 10 is first of all described in more detail. FIG. 4 shows a diagram for illustrating the switching characteristics of a zener diode. As is revealed by FIG. 4, the zener diode behaves highly resistive at a voltage U in the range above a negative diode voltage and below a positive diode voltage, so that no current I flows through the zener diode, i.e. the zener diode blocks in this region. As soon as the voltage U lies above the positive diode voltage of, for instance, 0.7V or below the negative diode voltage of, for instance, −2V, the zener diode abruptly becomes lowly resistive, so that current I can flow through the zener diode. This switching behavior of a zener diode is utilized with the electric circuits for semiconductor memories according to a second preferred embodiment of the present invention.

As is illustrated in FIGS. 2a and 2B, the second embodiment in which the polymer memory device 5 is coupled with a zener diode 10 may also be designed in two different variants that differ in the order of the diode 10 and the polymer memory cell 5. In the embodiment illustrated in FIG. 2A, the order of the series connection starts at the plate connection 4 with the polymer memory device 5 via the zener diode 10 to the capacitor 9. In the embodiment illustrated in FIG. 2B, the order of the series connection starts at the plate connection 4 with the zener diode 10 via the polymer memory device 5 to the capacitor 9. Depending on the layout or the optimization of the leaking current, the one or the other variant of the circuit may be preferred.

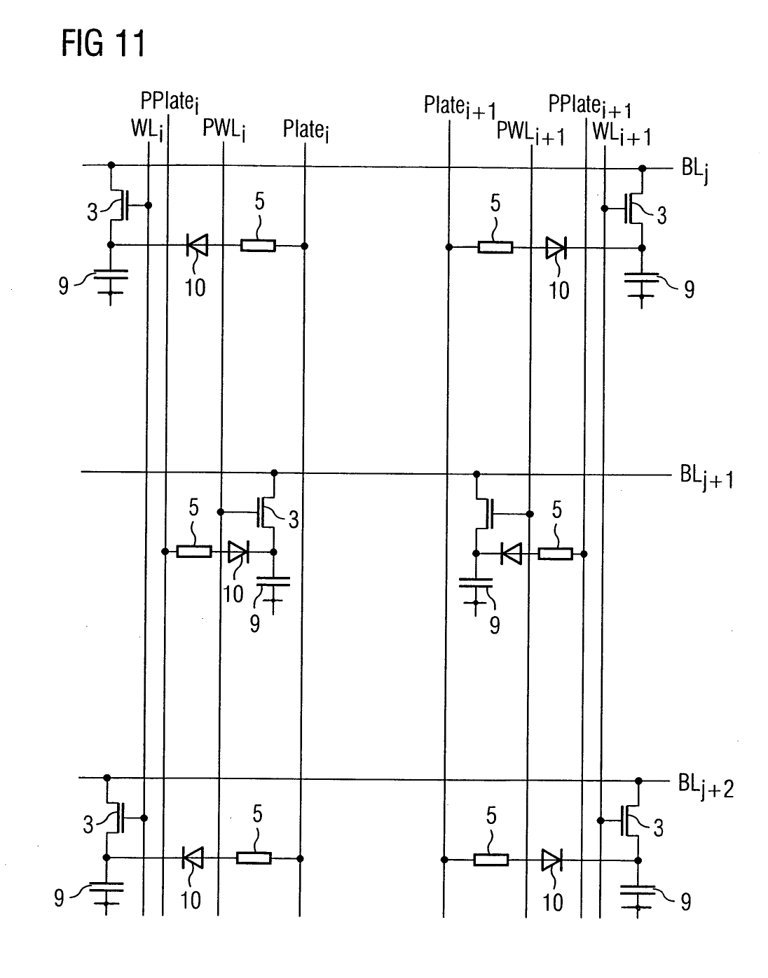

FIG. 11 shows an electric circuit for an inventive semiconductor memory according to the embodiment of the present invention illustrated in FIGS. 2A and 2B with a zener diode, wherein the semiconductor memory is designed according to the folded bit line concept. In accordance with the embodiment illustrated in FIG. 11, the folded bit line concept comprises a recurrent succession of electric lines that are arranged side by side and parallel to each other in the following order:

word line WLᵢ

passing plate line PPlateᵢ

passing word line PWLᵢ

plate line Plateᵢ

plate line Plateᵢ₊₁

passing word line PWLᵢ₊₁

passing plate line PPlateᵢ₊₁

word line WLᵢ₊₁

These electric lines are crossed orthogonally by bit lines BLⱼ and BLⱼ₊₁. The DRAM memory device comprises a word line transistor or selection transistor 3, respectively, and a capacitor 9. With respect to the bit line plane BLⱼ, the selection transistor 3 and the capacitor 9 of the DRAM memory device are each controlled via the word lines WLᵢ or WLᵢ₊₁, respectively, and the bit line BLⱼ. To this end, the word lines WLᵢ or WLᵢ₊₁, respectively, are each connected with the gates of the selection transistors 3 while the bit line BLⱼ is connected with the source/drain path of the selection transistors 3.

The non-volatile memory device comprises a polymer memory device 5 and a zener diode 10. On the one side, the polymer memory device 5 is connected with the zener diode 10, and on the other side with the plate line Plateᵢ or Plateᵢ₊₁, respectively. The zener diode 10 is connected with the capacitor 9 of the DRAM memory device via an appropriate node.

With respect to the bit line plane BLⱼ₊₁, the selection transistor 3 and the capacitor 9 of the DRAM memory device is controlled via the passing word lines PWLᵢ or PWLᵢ₊₁, respectively, and the bit line BLⱼ₊₁. To this end, the passing word lines PWLᵢ or PWLᵢ₊₁, respectively, are each connected with the gates of the selection transistors 3 while the bit line BLⱼ₊₁ is connected with the source/drain path of the selection transistors 3. The polymer memory device 5 is on the one side again connected with the zener diode 10, but on the other side with the passing plate line PPlateᵢ or PPlateᵢ₊₁, respectively. Accordingly, the control gate of the additional transistor 6 is contacted and controlled via the passing control gate line PCG. The next bit line plane BLⱼ₊₂ has the same structure as the bit line plane BLⱼ. This structure recurs as many times as desired, which is indicated by the orders i and i+1 or j, j+1 and j+2, respectively.

In the following, the operating mode of the circuits illustrated in FIGS. 2A and 2B for a semiconductor memory according to the present invention is described. For writing information contained in the DRAM memory device 3 into the non-volatile polymer memory cell 5, the word line 1 is first of all taken to a low state.

By applying a negative voltage at the plate connection 4 of, for instance, Vplate=−3.5V, it is effected that a voltage of approx. Vc−Vplate=5V is generated between the capacitor voltage at the node 8 to the plate connection 4. The capacitor voltage Vc of the DRAM memory device 9 is approx. 1.3V to 1.8V (high state of the DRAM memory device). This voltage lies above the writing voltage and is further sufficient to operate the zener diode 10 (at a setpoint of 2V) in the breakthrough and to thus apply a voltage of 3V at the polymer memory device 5. By the charge of the capacitor 9, information is written into the polymer memory device 5 in that the polymer memory resistance is changed, i.e. the polymer memory device 5 becomes lowly resistive.

If the capacitor 9 does not include any charge (low state of the DRAM memory device), the voltage difference Vc−Vplate=3.5V is not sufficient to apply the breakthrough voltage and the writing voltage. Then, the polymer memory 5 remains highly resistive and is therefore not written. This transfer of the information contained in the DRAM memory device 3 to the polymer memory devices 5 may again be effected in parallel on the entire chip on which there are a number of circuits illustrated in FIGS. 2A and 2B, or else in smaller memory blocks.

The operating mode or the method, respectively, for loading the respectively stored value from the non-volatile polymer memory 5 to the DRAM memory device 3 of the embodiment illustrated in FIGS. 2A and 2B does not differ substantially from the methods described in relation with FIGS. 1A and 1B. In the circuits illustrated in FIGS. 2A and 2B, for loading the respectively stored value from the polymer memory 5 to the DRAM memory device 3, the zener diode 10 is operated in breakthrough direction and the voltage at the plate connection 4 assumes a value that is higher by the diode voltage, e.g. Vplate=3V at a diode voltage of 0.7V.

In addition to the above-described operating modes for the transfer of information between the non-volatile polymer memory 5 and the volatile DRAM memory device 3, a regular DRAM operation is also possible with the inventive semiconductor memory even in the embodiment with a zener diode 10, in which the DRAM memory devices 3 are used as a conventional DRAM system memory. With this regular DRAM operation, the zener diode 10 blocks and a regular DRAM operation is possible. By connecting either the pn-junction of the zener diode 10 or the polymer memory 5 with the node 8, leaking currents can additionally be minimized. The plate connection 4 is kept at a voltage of Vplate=0V.

In the following, the operating mode for deleting the polymer memory devices 5 is described with the circuits illustrated in FIGS. 2A and 2B. Similar to the embodiment described in relation with FIGS. 1A and 1B, the polymer memory devices can, in the embodiment with the zener diode 10, be deleted both in the idle cycle of the DRAM memory if the DRAM memory device 3 is not accessed, and during the writing back of the information stored in the polymer memory devices or during the reading out of the respectively stored values (parallel thereto in another memory block) from the polymer memory devices 5, respectively. In so doing, all polymer memory devices 5 are deleted at the corresponding word line 1.

For deleting the polymer memory devices 5, the word line 1 is first of all opened, which effects a charge sharing or a charge equalization, respectively, between the precharged bit line 2 and the capacitor 9. Then, the voltage at the bit line 2 or at the capacitor 9, respectively, increases or decreases and assumes, depending on the respectively stored value, finally a value of approx. 0.9 or approx. 1.1V in the manner that has been described above. Prior to the evaluation by means of a sense amplifier, the word line 1 is closed. If a voltage of −5V is applied to the plate connection 4, the voltage at the polymer memory device 5 is composed of Vplate−Vdiode−0.9V or of Vplate−Vdiode−1.1V, respectively. In both cases, the voltage is thus higher than the deleting voltage VDel of the polymer memory device 5, this causing all polymer memory cells 5 of the corresponding word line 1 to be deleted.

Subsequently, after the decreasing of the voltage at the plate connection 4 and with a closed control gate 7, the value that has now been amplified by the sense amplifier is again written in the capacitor 9 of the DRAM memory device in that the word line transistor 3 is opened again. Alternatively, after the reading out of the voltage of the capacitor 9 to the bit line 2 (charge equalization), the capacitor 9 can be (completely) discharged, for instance, via the plate connection 4, this making it possible to decrease the voltage for the writing process at the plate connection to approx. Vplate=3.7V.

In the following Table, the voltages or logic levels, respectively, required for the above-described operating modes are listed for an inventive semiconductor memory according to the second preferred embodiment with a zener diode.

| | V plate line | V word line |
|---|---|---|
| Writing from | −3.5 V | Low |
| DRAM into poly- | | |
| mer memory | | |
| Loading, from | 3 V | Low |
| polymer memory | | |
| into DRAM | | |
| DRAM operation | Approx. 0 V | Depending on |
| | | the process |
| Deleting of | Approx. −5 V | As described |
| polymer memory | | above |

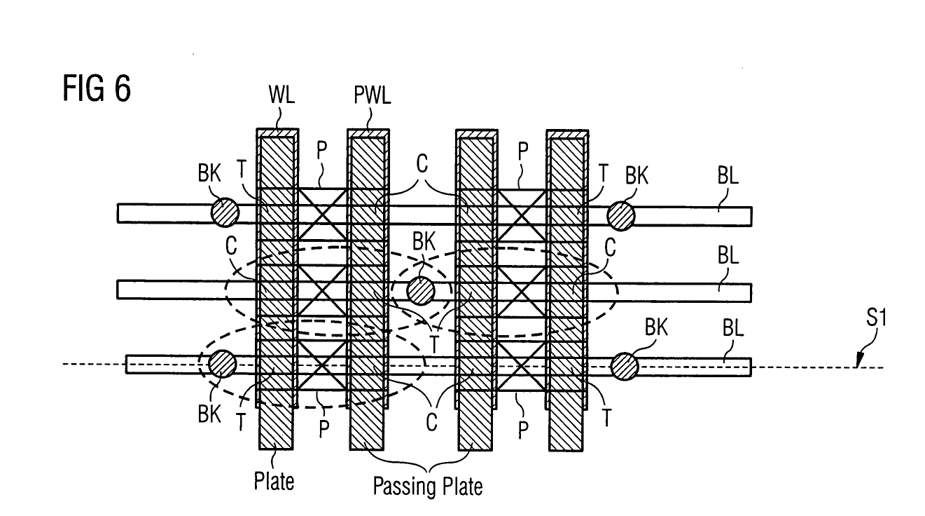

In the following, the structure and the layout for an inventive semiconductor memory is described by means of FIGS. 5 to 10. FIG. 5 shows a lateral sectional view through a semiconductor substrate in which an inventive semiconductor memory is structured in the embodiment with a zener diode according to the layout illustrated in FIG. 6 and the circuit diagram according to the folded bit line concept illustrated in FIG. 11. The section plane of the lateral view of FIG. 5 is indicated in FIG. 6 by a dashed line S1.

The structure illustrated in FIG. 5 comprises the same succession of electric lines as illustrated in FIG. 6. The electric lines are arranged side by side on a semiconductor substrate in a first plane in the following, recurrent order:

word line WL

passing word line PWL

passing word line PWL

word line WL

In a second plane above the first plane, the following electric lines are arranged:

plate line Plate

passing plate line PPlate

passing plate line PPlate

plate line Plate

As results from FIG. 5, the plate line Plate and the passing plate line Pplate are arranged in a different layer or plane, respectively, than the other electric lines. The electric lines are crossed orthogonally by a bit line BL. While the course of the bit line BL lies in the paper plane, the electric lines listed above each run perpendicular to the paper plane. From the bit line BL, there extend tungsten vias W and abut at the opposite side between two word lines WL to an N+ doped diffusion region that is illustrated by a dashed area.

Below the adjacent passing word lines PWL, two respective trench capacitors TK are formed, at the upper end of which an L-shaped buried strap BS each is arranged as conducting transistor contact means. The trench capacitors TK are separated from each other by a shallow trench isolation layer STI. An N+ doped diffusion region each is provided at the sides of the L-shaped buried straps BS that are opposite to the shallow trench isolation layer STI. Between the buried strap BS and the passing word line PWL, a respective thick oxide layer Ox is formed to electrically isolate both the two L-shaped buried straps BS and the adjacent passing word lines PWL from each other.

Below the word lines WL, there is formed a respective gate oxide GO, whereby the N+ diffusion region below the tungsten vias W of the bit line BL and the adjacent N+ diffusion region that is adjacent to the L-shaped buried strap BS above the trench capacitor TK are electrically coupled with each other. This way, the N+ diffusion region below the tungsten vias W of the bit line BL forms, together with the N+ diffusion region adjacent to the L-shaped buried strap BS above the trench capacitor TK, the above-mentioned selection transistor of the DRAM memory device, which is controlled via the word line WL.

Between the passing word lines PWL and the trench capacitors TK, the forming of a transistor is prevented by a respective thick oxide layer Ox, and the capacitor for the DRAM memory device is generated instead. Below the thick oxide layer Ox, the L-shaped buried straps BS form a conducting transistor connection between the trench capacitor TK and the N+ doped source/drain region of the selection transistor.

Between the plane with the plate lines Plate and the plane with the word lines WL, a polymer memory device P is positioned. A P+ doped polysilicon contact that connects the N+ doped source/drain region via a suitable contact layer K with the polymer memory device P is adjacent to the N+ doped source/drain region of the selection transistor below the word line WL. This P+ doped polycontact below the polymer memory device P forms, together with the N+ doped source/drain region between the word line WL and the passing word line PWL, a zener diode.

Above the polymer memory device P, there is positioned the plate line Plate that is connected with the polymer memory device P also via a suitable contact layer K. The polymer memory device P may comprise a layer succession as has been described initially in conjunction with polymer memory devices. Accordingly, the material for the contact layer K above and below the polymer memory device P is, as a rule, different and depends on the type of polymer memory device P used. Adjacent to the plate line Plate, the passing plate line PPlate is arranged, which also serves the contacting of the polymer memory device P, as is described in relation with FIG. 11.

FIGS. 6 to 9 each show a schematic representation of the layout for a semiconductor memory according to a preferred embodiment of the present invention. FIG. 6 illustrates a preferred layout for an inventive semiconductor memory for use in combination with a zener diode. This layout comprises at least one word line WL of polysilicon which is superposed by a plate line of metal that is arranged in parallel thereto, as well as at least one passing word line PWL which is superposed by a passing plate line that is arranged in parallel thereto. These electric lines are crossed orthogonally by bit lines BL. On the bit line BL, bit line contacts BK each are arranged, via which the contact to the corresponding bit line BL is made.

At particular crosspoints with the bit line BL, a respective shallow trench isolation layer (not illustrated) may be provided between the word line WL and the plate line thereabove, as well as between the passing word line PWL and the passing plate line thereabove, so as to form either a transistor T or a capacitor C. A word line WL or a passing word line PWL forms, at a respective crosspoint with a bit line BL, only a transistor if no shallow trench isolation layer is positioned therebetween. If, at the crosspoint with a bit line BL, a shallow trench isolation layer STI is positioned between a word line WL and a passing word line PWL, no transistor is generated, but a capacitor C. This way, respective capacitors C of a DRAM memory device may be formed at particular crosspoints between the bit line BL with the word lines WL and the passing word lines PWL. Between the word line WL and the passing word line PWL, respective polymer memory devices P are formed in the spacing at the crosspoints with the bit line BL.

The dashed ovals illustrate memory cells which comprise both a volatile memory device and a non-volatile memory device. These memory cells each comprise a bit line contact BK, a capacitor C of a DRAM memory device, a selection transistor T that is generated at the crosspoint with the word line WL, a polymer memory device P, and a zener diode.

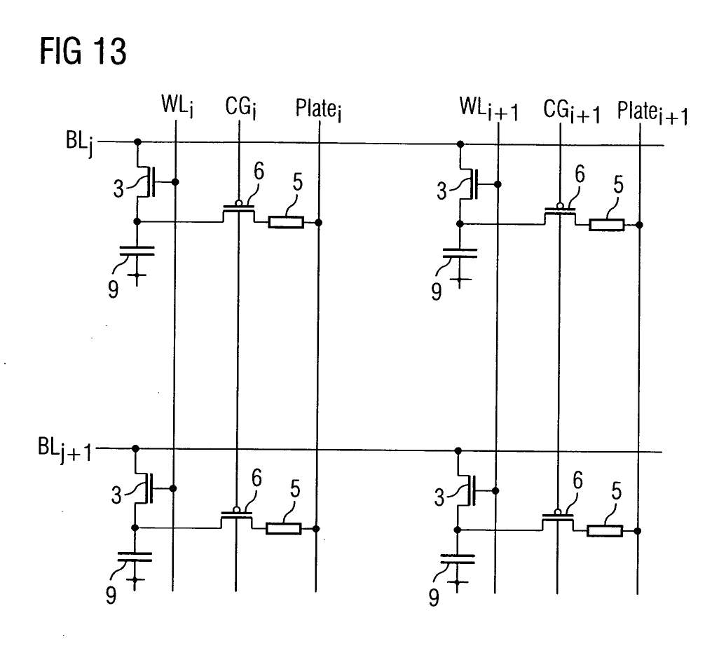

FIG. 13 shows an electric circuit diagram for a semiconductor memory according to the first embodiment of the present invention with an additional transistor, wherein the semiconductor memory is designed according to the open bit line concept. The open bit line concept comprises a recurrent succession of electric lines that are arranged side by side and in parallel to each other in the following order:

word line WLᵢ

control gate line CGᵢ

plate line Plateᵢ

word line WLᵢ₊₁

control gate line CGᵢ₊₁

plate line Plateᵢ₊₁

These electric lines are crossed orthogonally by bit lines BLⱼ and BLⱼ₊₁. The volatile DRAM memory device comprises a word line transistor or selection transistor 3, respectively, and a capacitor 9, which are correspondingly controlled via the word lines WL and the bit lines BL. To this end, the word lines WLᵢ₊₁ are connected with the gates of the selection transistors 3 while the bit lines are connected with the source/drain paths of the selection transistors 3.

The non-volatile memory device comprises a polymer memory device 5 and an additional transistor 6. On the one side, the polymer memory device 5 is connected with the additional transistor 6, and on the other side with the plate line. The control gate of the additional transistor 6 is contacted and controlled via the control gate line CG. Via a node, the additional transistor 6 is connected with the capacitor 9 of the DRAM memory device. This structure recurs as many times as desired, which is indicated by the orders i and i+1.

With the folded bit line concept illustrated in FIGS. 5, 6, 9, 10, 11, and 12, the triggering of a word line WL effects that only every second bit line BLⱼ or BLⱼ₊₂, respectively, can be connected or opened, respectively. This way, the respective bit line BLⱼ₊₁ that is adjacent to an opened bit line BLⱼ and that is not connected or opened, respectively, can be used as reference for the sense amplifier. Since a possible noise at both bit lines BLⱼ or BLⱼ₊₁, respectively, exists to an approximately equal extent, there results the possibility of separating the noise signal from the data signal. With the folded bit line concept, both the bit lines BLⱼ and the reference bit lines BLⱼ₊₁ are precharged during the reading out of the DRAM memory devices. With the open bit line concept illustrated in FIG. 13, a bit line adjacent to a bit line BLⱼ₊₁ cannot be used as a reference bit line, but a bit line from another memory block has to be used as a reference bit line.

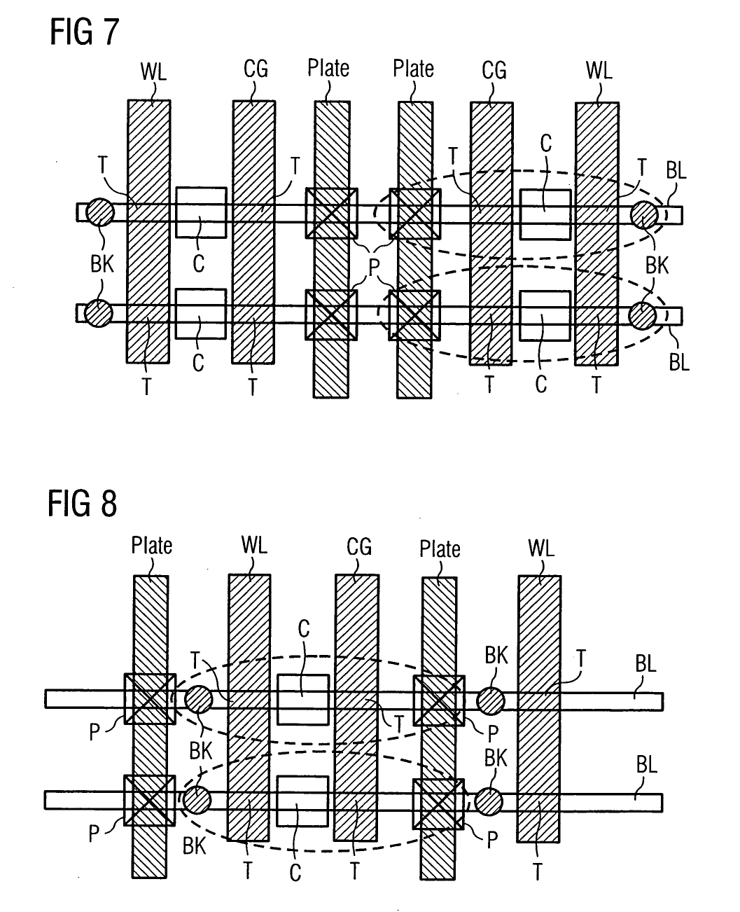

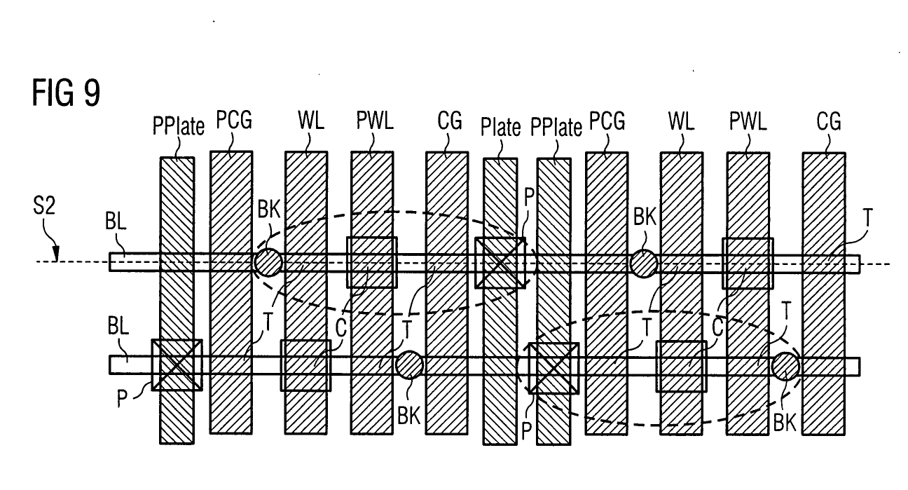

In each of FIGS. 7 and 8, a preferred layout for an inventive semiconductor memory with the structure of an open bit line concept is illustrated schematically. The open bit line concept illustrated in FIG. 7 comprises a succession of electric lines that are arranged side by side and parallel to each other in the following order:

word line WL

control gate line CG

plate line Plate

plate line Plate

control gate line CG

word line WL

These electric lines are crossed orthogonally by bit lines BL. On the bit line BL, bit line contacts BK for contacting the corresponding bit line BL are arranged. At the crosspoints of the two plate lines Plate with the bit lines BL, respective polymer memory devices P are formed. Between the word lines WL and the control gate lines CG that are arranged in parallel to each other, respective capacitors C of a DRAM memory device are formed on the bit lines BL.

By the dashed ovals, memory cells are illustrated that comprise both a volatile memory device and a non-volatile memory device. These memory cells each comprise a bit line contact BK, a capacitor C of a DRAM memory device, a selection transistor T that is generated at the crosspoint with the word line WL, a control transistor T arranged at the crosspoints of word line WL and the control gate line CG, and a polymer memory device P.

The open bit line concept illustrated in FIG. 8 comprises a succession of electric lines that are arranged side by side and in parallel to each other in the following order:

plate line Plate

word line WL

control gate line CG

plate line Plate

word line WL

These electric lines are crossed orthogonally by bit lines BL. Between the plate line Plate and the word line WL that runs parallel thereto, the bit lines BL are each provided with bit line contacts BK for contacting the corresponding bit line BL. At the crosspoints of the two plate lines Plate with the bit lines BL, respective polymer memory devices P are formed. Between the word line WL and the parallel control gate line CG, respective capacitors C of a DRAM memory device are formed on the bit lines BL.

The dashed ovals illustrate memory cells that comprise both a volatile memory device and a non-volatile memory device. These memory cells each comprise a bit line contact BK, a capacitor C of a DRAM memory device, a selection transistor T, a control transistor T, and a polymer memory device P.

FIG. 9 shows a preferred embodiment for a layout of an inventive semiconductor memory for realizing the circuit diagram according to the folded bit line concept illustrated in FIG. 12. This layout according to the folded bit line concept comprises a succession of electric lines that are arranged side by side and preferably in parallel to each other on a semiconductor substrate in the following recurrent order:

passing plate line PPlate

passing control gate line PCG

word line WL

passing word line PWL

control gate line CG

plate line Plate

passing plate line PPlate

passing control gate line PCG

word line WL

passing word line PWL

control gate line CG, etc.

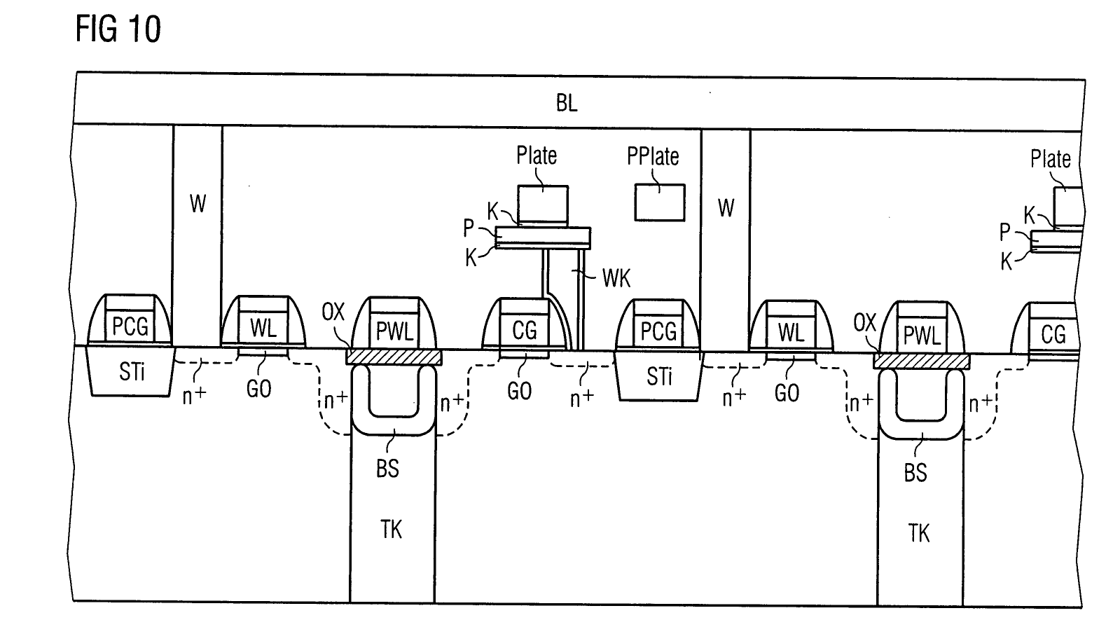

These electric lines are crossed orthogonally by bit lines BL. The dashed line S2 running through the upper bit line indicates the section plane of the lateral view of FIG. 10. On the bit line BL, respective bit line contacts BK for contacting the corresponding bit line BL are arranged. At particular crosspoints of the two passing plate lines PPlate and the plate line Plate with the bit lines BL, respective polymer memory devices P are formed.

At the crosspoints of the two passing word lines PWL with the bit lines BL, either capacitors C of a DRAM memory device or transistors T are formed, wherein these are the above-described word line transistors or selection transistors, respectively, of the DRAM memory device. At particular crosspoints of the two control gate lines CG and at the crosspoints of the two passing control gate lines PCG with the bit lines BL, transistors T are formed, wherein these are the above-described additional transistors of the polymer memory devices.

The dashed ovals illustrate memory cells that comprise both a volatile memory device and a non-volatile memory device. These memory cells each comprise a bit line contact BK, a capacitor C of a DRAM memory device, a selection transistor T, an additional control transistor T, and a polymer memory device P.

FIG. 10 shows a lateral sectional representation through a semiconductor substrate in which there is structured an inventive semiconductor memory having a structure for realizing the layout illustrated in FIG. 9 and in accordance with the circuit diagram according to the folded bit line concept illustrated in FIG. 12. The section plane of the lateral view of FIG. 10 is indicated in FIG. 9 by a dashed line S2. The structure illustrated in FIG. 10 comprises the same succession of electric lines as has already been illustrated in FIG. 9. The electric lines are therefore arranged in the following recurrent order side by side on a semiconductor substrate in a first plane:

passing control gate line PCG

word line WL

passing word line PWL

control gate line CG

passing control gate line PCG

word line WL

passing word line PWL

control gate line CG, etc.

In a second plane above the first plane, the following electric lines are arranged:

plate line Plate

passing plate line PPlate

FIG. 10 thus shows that the plate line Plate and the passing plate line Pplate are arranged in a layer or plane, respectively, which is different from that of the remaining electric lines. All the electric lines are crossed orthogonally by a bit line BL of metal. While the course of the bit line BL lies in the paper plane, the above-listed electric lines each run perpendicular to the paper plane. From the bit line BL there extend tungsten vias W and abut at the opposing side between the passing control gate line PCG and the word line WL to an N+ doped diffusion region. The N+ doped diffusion regions are each illustrated by dashed areas.

Below the passing word line PWL there is formed a trench capacitor TK, wherein a U-shaped buried strap BS is arranged as a conducting transistor contact means in the upper portion of the trench capacitor TK. On both sides of the U-formed buried strap BS, an N+ doped diffusion region each is provided. Between the buried strap BS and the passing word line PWL there is formed a thick oxide layer Ox to electrically isolate the two N+ doped diffusion regions adjacent to the buried strap BS from each other.

Below the word line WL, a gate oxide GO is formed, whereby the N+ diffusion region below the tungsten via W of the bit line BL is electrically coupled to the adjacent N+ doped diffusion region that is adjacent to the buried strap BS above the trench capacitor TK. This way, the N+ doped diffusion region below the tungsten via W of the bit line BL forms, together with the N+ doped diffusion region that is adjacent to the buried strap BS above the trench capacitor TK, the abovementioned selection transistor of the DRAM memory device which is controlled via the word line WL.

Between the passing word line PWL and the trench capacitor TK, the forming of a transistor is prevented by a thick oxide layer Ox, and the capacitor for the DRAM memory device is formed instead. Below the thick oxide layer Ox, the U-shaped buried strap BS produces a conducting transistor connection between the trench capacitor TK and the N+ doped source/drain region of the selection transistor.

A further N+ doped region below the control gate line CG is connected via a tungsten contact WK and suitable contact layers K with a polymer memory device P that is arranged between the plane with the plate line Plate and the plane with the control gate line CG. Above the polymer memory device P there is positioned the plate line Plate that is connected with the polymer memory device P also via a suitable upper contact layer K. The polymer memory device P may comprise several layers, as has been described initially in conjunction with polymer memory devices. Accordingly, the material for the contact layer K above and below the polymer memory device P is, as a rule, different and depends from the type of polymer memory device P used.

Below the control gate line CG, a further gate oxide layer GO is formed, whereby the N+ doped diffusion region below the tungsten contact WK of the polymer memory device P is electrically coupled with the adjacent N+ diffusion region that is adjacent to the buried strap BS above the trench capacitor TK. This way, the N+ diffusion region below the tungsten contact WK of the polymer memory device P forms, together with the N+ diffusion region that is adjacent to the buried strap BS above the trench capacitor TK, the above-mentioned additional transistor of the polymer memory device P, which is controlled via the control gate line CG.

Below the passing control gate line PCG there is positioned a shallow trench isolation layer STI. The shallow trench isolation layer STI prevents an electric coupling between the N+ doped diffusion region below the tungsten vias W and the N+ doped diffusion region that is adjacent to the U-shaped buried strap BS. This way, the N+ doped source/drain region of the selection transistor is electrically isolated from the N+ doped source/drain region of the additional transistor and thus from the tungsten contact WK of the polymer memory device P.

What is claimed is:

1. A semiconductor memory with a volatile memory device, and with a non-volatile memory device, wherein the volatile memory device is electrically coupled with the non-volatile memory device, and the non-volatile memory device comprises a polymer memory device that is adapted to be switched between two states of information.

2. The semiconductor memory according to claim 1, wherein the polymer memory device is electrically coupled with the DRAM memory device such that on switching off a supply voltage of the DRAM memory device, the information that has last been stored therein can be loaded into the polymer memory device.

3. The semiconductor memory according to claim 1, wherein the polymer memory device is electrically coupled with the DRAM memory device such that on switching on a supply voltage of the DRAM memory device, the information stored in the polymer memory device can be loaded into the DRAM memory device, so that, after the switching on of the supply voltage, a same state of information can be available in the DRAM memory device that was available prior to switching off of the supply voltage from the DRAM memory device.

4. The semiconductor memory according to claim 1, wherein the polymer memory device comprises at least one controllable first contact, one second contact, and one memory cell that comprises an electrochemically variable polymer material that comprises at least two different molecule or polymer layers, respectively, which form an electrochemical Red/Ox pair.

5. The semiconductor memory according to claim 1, wherein the polymer memory device is electrically coupled with an additional transistor that is adapted to be controlled via a control gate.

6. The semiconductor memory according to claim 1, wherein additional transistor or the polymer memory device is connected with a memory capacitor of the DRAM memory device.

7. The semiconductor memory according to claim 6, wherein the polymer memory device is connected in series between the additional transistor and the capacitor, or the additional transistor is connected in series between the polymer memory device and the capacitor.

8. The semiconductor memory according to claim 1, wherein the polymer memory device is electrically connected with a zener diode.

9. The semiconductor memory according to claim 8, wherein the polymer memory device is connected in series between the zener diode and the capacitor, or the zener diode is connected in series between the polymer memory device and the capacitor.

10. A method for writing a polymer memory device of a semiconductor memory, comprising:
setting a word line to the polymer memory device to a low state and setting a control gate at an additional transistor of the polymer memory device to a high state;
applying a negative voltage to a plate connection of the polymer memory device; and
writing the information included in a volatile memory device into the non-volatile polymer memory device.

11. The method according to claim 10, wherein a negative voltage applied to the plate connection of the polymer memory device is selected such that a voltage above a writing voltage of the polymer memory device is generated between a node between a capacitor and the word line and the plate connection of the polymer memory device.

12. A method for transferring information stored in a polymer memory device from the polymer memory device to a volatile memory device of a semiconductor memory, comprising:
setting a voltage present at a capacitor to a defined voltage level;
closing a word line and opening a control gate;
applying a positive voltage that is lower than a deleting voltage of the polymer memory device to a plate connection of the polymer memory device; and
transferring the information stored in the polymer memory device from the polymer memory device to the volatile memory device.

13. The method according to claim 12, wherein, on setting of the defined voltage level, the capacitor is taken to a voltage level of approx. 0V by opening the word line and connecting a bit line with a ground connection.

14. A method for deleting a polymer memory device of a semiconductor memory, comprising:
opening at least one word line;
performing a charge equalization between a bit line and a capacitor;
closing the word line and opening a control gate of a volatile memory device; and
applying a negative voltage to a plate connection so that a voltage is present at the polymer memory device that is higher than a deleting voltage of the polymer memory device.

15. The method according to claim 14, wherein the method for deleting the polymer memory device is performed while the volatile memory device is in an idle cycle.

16. The method for operating a semiconductor memory according to claim 1, wherein the volatile memory device is a DRAM memory device and is used as a conventional DRAM system memory, wherein a line of an additional transistor is in a low state or has a negative voltage or blocks a zener diode, respectively.

17. A memory field having at least one volatile memory device, and at least one non-volatile polymer memory device, wherein the volatile memory device is electrically coupled with the polymer memory device, comprising:
a first layer comprising electric supply lines or bit lines, respectively;
at least one second layer being arranged on the first layer and being in electric connection therewith, the second layer comprising either the at least one volatile memory device or at least a first chemical compound that is adapted to be reversibly transferred from a reduced form to an oxidized form; and
a third layer arranged on the second layer, comprising electric supply lines or word lines, respectively, that are arranged such that the electric supply lines or bit lines, respectively, of the first layer and the electric supply lines or word lines, respectively, of the third layer form crosspoints at which the volatile memory device or the polymer memory device is arranged, wherein the electric supply lines or word lines, respectively, of the third layer are electrically connected with the polymer memory device via a respective additional transistor.

18. The memory field according to claim 17, wherein the electric supply lines of the first layer and the electric supply lines of the third layer each are arranged in parallel to each other and are, in a plane view of the memory field, arranged in a rectangular matrix.

19. A structure for a semiconductor memory comprising at least the following electric lines arranged on a semiconductor substrate in a first plane:
a word line;
a passing word line;
a control gate line;
a passing control gate line;
a plate line (Plate); and
a passing plate line
are arranged in second or third planes deviating from the first plane.

20. The structure according to claim 19, wherein a polymer memory device and a metal contact are provided between the first plane and the plate line.

21. The structure according to claim 19, wherein a polymer memory device and a P+ doped polysilicon contact are provided between the first plane and the plate line.

22. The structure according to claim 19, wherein a zener diode is formed from a P+ doped polysilicon contact and a N+ doped source/drain region of a selection transistor or word line transistor, respectively.
